(19) United States
(12) Patent Application Publication
(10) Pub. No.: US 2007/0202636 A1
(43) Pub. Date: Aug. 30, 2007

(54) Method of controlling the film thickness uniformity of PECVD-deposited silicon-comprising thin films

(75) Inventor: Soo Young Choi, Fremont, CA (US)

Correspondence Address: SHIRLEY L. CHURCH, ESQ., P.O. BOX 81146, SAN DIEGO, CA, 92138, US

(73) Assignee: Applied Materials, Inc.

(21) Appl. No.: 11/709,438

(22) Filed: Feb. 21, 2007

Related U.S. Application Data
(60) Provisional application No. 60/776,024, filed on Feb. 22, 2006.

(51) Int. Cl. H01L 21/84; H01L 21/00

(52) U.S. Cl. 438/149

(57) ABSTRACT

A method which can be used to provide PECVD deposited silicon-comprising films of uniform thickness across large substrate surfaces, where the minimal dimension along an edge of the substrate or the minimum equivalent diameter is about 500 mm. Further, the uniform film can be produced under process conditions which provide a process window which enables easy control over the process. The method makes use of a combination of process steps where the individual process steps are easy to control and provide film profile repeatability over the substrate surface but do not provide film thickness uniformity over the substrate surface. The combination of process steps provide film thickness uniformity over the substrate surface.

### RELATED APPLICATIONS

This application is based on U.S. Provisional Application Ser. No. 60/776,024, filed Feb. 22, 2006, which is currently pending, and under which priority is claimed in accordance with 35 U.S.C. §120. This application is related to other pending applications pertaining to the PECVD deposition of various thin films over large surface areas, such as U.S. application Ser. No. 10/829,016, filed Apr. 20, 2004; U.S. application Ser. No. 10/889,683, filed Jul. 12, 2004; U.S. application Ser. No. 10/897,775, filed Jul. 23, 2004; and, U.S. application Ser. No. 10/962,936, filed Oct. 12, 2004, each of which are hereby incorporated by reference in its entirety.

### BACKGROUND OF THE INVENTION

1. Field of the Invention

The present invention pertains to a method of controlling the thickness profile of a silicon-comprising film deposited using PECVD (plasma-enhanced chemical vapor deposition) over a large surface area, such as a flat substrate having a rectangular dimension of about 500 mm or larger on a side. Typical dimensions might be 2,000 mm×2,500 mm or larger.

2. Brief Description of the Background Art

Current interest in thin film transistor (TFT) arrays is particularly high because these devices are used in liquid crystal active matrix displays of the kind often employed for computer and television flat panels. The liquid crystal active matrix displays may also contain light emitting diodes for back lighting. Further, organic light emitting diodes (OLEDs) have been used for active matrix displays, and these organic light emitting diodes require TFTs for addressing the activity of the displays.

The TFT arrays are typically created on a flat substrate. The substrate may be a semiconductor substrate, or may be a transparent substrate, such as a glass, quartz, sapphire, or a clear plastic film. FIG. 1 shows a TFT of the kind which employs amorphous silicon films of the kind which are related to the present invention. FIG. 1 illustrates a schematic cross-sectional view of a thin film transistor structure of the kind which employs both amorphous silicon and doped amorphous silicon films. This kind of thin film transistor is frequently referred to as an inverse staggered α-Si TFT with a SiNₓ layer as a gate insulator, or as a back channel etch (BCE) inverted staggered (bottom gate) TFT structure. This structure is one of the more preferred TFT structures because the gate dielectric (SiNₓ) and the intrinsic as well as n+ (or p+) doped amorphous silicon films can be deposited in a single PECVD pump-down run. The BCE TFT shown in FIG. 1 requires the use of only four or five patterning masks during fabrication, an advantage over previous TFT designs.

The substrate for a TFT structure typically comprises a material that is essentially optically transparent in the visible spectrum, such as glass, quartz, sapphire, or a clear plastic. The substrate may be of varying shapes or dimensions. Typically, for TFT applications, the substrate is a glass substrate with a surface area greater than about 500 mm². A surface area of greater than about 25,000 mm² is not uncommon. To provide a general understanding of the relationship of the PECVD deposited amorphous silicon films relative to the other components of the TFT, a brief description of the overall structure of a inverse staggered α-Si TFT with a SiNₓ layer as a gate insulator is provided, with reference to FIG. 1.

A conductive layer 102 is typically sputter deposited over a glass substrate 101 using techniques known in the art. The glass substrate 101 frequently has a thickness ranging from about 0.5 mm to about 1.1 mm. The conductive layer 102 is typically a bilayer, where the bottom portion of the layer is a chrome layer, with an overlying layer of an aluminum neodymium alloy. The conductive layer is commonly pattern etched using a wet etch process known in the art to provide conductive electrodes 102b, as shown in FIG. 1. A layer 103 of n⁺ a-Si/a-Si/a-SiNₓ:H is blanket applied by a PECVD process which is described in detail in U.S. patent application Ser. No. 10/829,016, which was previously incorporated by reference herein. Following the deposition of layer 103, a layer 104 of a-Si is blanket deposited using a PECVD process. Finally, a layer 105 of n+ doped a-Si is blanket applied by processes known in the art, such as a PECVD process, to provide a conductive layer which can patterned etch to become the source and drain regions for the TFT device. With reference to FIG. 1, a-Si patterned layers 104 of a-Si and 105 of n+ doped a-Si have been dry etched to produce the pattern shown, using techniques known in the art. The doped semiconductor layer 105 may comprise n-type (n+) or p-type (p+) doped polycrystalline, microcrystalline, or amorphous silicon. Doped semiconductor layer 105 is typically deposited to a thickness within a range of about 100 Å to about 3000 Å. An example of the doped semiconductor layer 105 is n+ doped a-silicon film. The bulk semiconductor layer 104 and the doped semiconductor layer 105 are lithographically patterned and etched using conventional techniques to define a mesa of these two films over the gate dielectric insulator, which also serves as storage capacitor dielectric. The doped semiconductor layer 105 directly contacts portions of the bulk semiconductor layer 104, forming a semiconductor junction.

Subsequent to pattern etching of layers 104 and 105, a blanket sputtering deposition of a conductive layer such as a chrome layer is carried out using techniques known in the art. A portion of a patterned chrome layer 106 subsequently becomes part of the source and drain regions of the TFT device. Chrome layer 106 is pattern dry etched, using techniques known in the art.

Subsequent to patterning of Chrome layer 106, the portion of the n⁺ a-Si layer 105 which was exposed by the patterned dry etch of chrome layer 106 is etched back using techniques known in the art, where the n⁺ a-Si layer 105 is etched completely through, and is “overetched” into underlying layer 104 of a-Si, as shown in FIG. 1. A passivation layer of a-SiNₓ:H dielectric is applied over the substrate surface using PECVD, according to the method described in detail in U.S. patent application Ser. No. 10/829,016; this is followed by dry etching to produce the patterned passivation layer 107.

Finally, a layer of indium tin oxide is blanket sputter deposited over the substrate using techniques known in the art; the indium tin oxide layer is pattern dry etched to produce patterned indium tin oxide layer 108, This optically clear conductive layer enables the use of the TFT device for display applications.

Fujiyama et al., in an article entitled: “New reactor for large-area amorphous silicon thin films by scanning plasma method”, Proceedings of the Tenth International Conference on Chemical Vapor Deposition, Electrochem Soc., Pennington, N.J., USA, p. 831-8 (1987), described a specialized plasma CVD reactor for fabrication of large area solar cells. The article teaches that conventional plasma CVD reactors, which make use of an RF discharge, make it difficult to obtain a uniform alpha silicon film thickness because of the inhomogeneous RF discharge between large-area electrodes used for film formation on large surface substrates. A different plasma CVD reactor is recommended which enables the scanning plasma method (SPM). The specialized reactor is described in the article and is said to be capable of uniformly depositing a-SiH thin films on substrates which are 1,000 mm by 2,000 mm.

South Korean patent application number KR200087601, filed Dec. 30, 2000, describes a thin film transistor and a method of fabricating the transistor, which is said to provide improved uniformity of the thickness of an amorphous silicon layer by controlling spacing between the electrodes and deposition pressure of a PECVD apparatus. In particular, the semiconductor layer is said to consist of first and second semiconductor layers, which are sequentially laminated. The edge of the first semiconductor layer is thinner or thicker than the center of the first semiconductor layer. The edge of the second semiconductor layer is thicker or thinner than the center of the second semiconductor layer. The semiconductor layer is said to be formed using a PECVD apparatus.

A description of various surface wave effects which may affect power density distribution appears in an article by M. A. Lieberman et al., “Standing wave and skin effects in large-area, high-frequency capacitive discharges”, Plasma Sources Sci. Technol., Vol. 11, pp. 283-293 (2002), and M. A. Lieberman, Principles of Plasma Discharges and Materials Processing, Wiley-Interscience, New York (1994), for example.

FIGS. 2A and 2B illustrate theoretic modeling of a cylindrical parallel plate, capacitively coupled reactor. The reactor 200, shown in cross-section in FIG. 2A, includes an upper electrode 202 and a lower electrode 204, which typically supports a substrate (not shown). RF power source 206 provides power to upper electrode 202, to generate a plasma 208 between upper electrode 202 and lower electrode 204. FIG. 2B shows a cross-section taken at the center of the plasma region 208, where R is the radius of the electrode (in meters), d is half the plasma width (in millimeters), L is the half-spacing between the electrodes (in millimeters), and s is the plasma sheath width (in millimeters).

Evanescent wave skin effects exhibit a sharp maximum at the edge, then rapidly decay toward the center. With proper engineering of the plasma reactor periphery, evanescent wave skin effects can typically be expressed outside the area of the substrate surface.

Surface wave skin effects begin to have a significant effect on plasma uniformity when the plasma electron density (nₑ) reaches a certain threshold, which was determined to be nₑ=1.39×10¹¹/(dR) cm⁻³ (where d is half of the plasma width in mm, and R is the radius of the electrode in meters). In typical PECVD film deposition processes, nₑ≦10⁹/cm³. Therefore, this criterion is satisfied for most PECVD chambers, even for the larger rectangular substrates where the equivalent R (the half diagonal dimension of the substrate) is equivalent to 1.39 meters, and half-width of the plasma, d, is about 10 millimeters. Therefore, the non-uniform RF surface wave skin effects are generally negligible in a PECVD process scale up.

The most important of the plasma surface wave effects are surface standing wave effects, which become significant when the total substrate surface area increases beyond about 1 square meter. Surface standing wave effects can have a significant effect on the uniformity of film thickness and other film properties across the substrate surface.

In the past, the basic principle behind the scale-up of PECVD processes was to maintain the intensive deposition parameters (such as process chamber pressure, electrode spacing, and substrate temperature) constant, while proportionately increasing the extensive deposition parameters (such as process gas flow rates and RF power to the plasma). However, due to ever increasing substrate sizes, which now include a surface area of 30,000 mm² or larger, most PECVD processes do not properly scale up by adjustment of extensive deposition parameters alone, for various reasons. Furthermore, with respect to the extensive deposition parameters, fundamental problems may arise in the uniformity of film thickness and other film properties across the substrate surface as a consequence of non-uniform RF power density within the processing chamber.

While it is possible to adjust process parameters of the kind discussed above, there are limits to which process parameters can be adjusted and still provide ease of manufacturability and control over the process. At some process variable settings, a very small change in a variable has a very large effect on the product produced, when this happens control issues arise which manufacturability and yield in the manufacturing process. Those working in the industry refer to the “process window” indicating the tolerance of the process for adjustment in the process variables while maintaining an acceptable yield. While it may be possible to optimize a set of operating variables to produce exactly the desired result in a deposited film, it may be very difficult to keep control over the process at the optimized set of operating variables.

### SUMMARY OF THE INVENTION

We have developed a method which can be used to provide PECVD deposited silicon-comprising films of uniform thickness across large substrate surfaces, where the minimal dimension along an edge of the substrate or the minimum equivalent diameter is about 500 mm. Further, the uniform film can be produced under process conditions which provide a process window which enables easy control over the process. Example silicon-comprising films which may be uniformly deposited using the method include a-SiNₓ:H and a-Si films which are useful in the manufacture of TFT structures on flat panel displays, for example and not by way of limitation. Other silicon-containing films such as polycrystalline silicon films and microcrystalline silicon films may also be deposited using the method. All of these films may be doped or undoped, depending on the functionality required. The film deposition rate is typically greater than 1000 Å/min, and frequently more than about 2,000 Å/min. While it is possible to shape the film thickness over the substrate surface to various profiles by selecting particular nominal values for the processing variables used to deposit the film, some combinations of process variables cannot be controlled in a manner such that the film deposition process is repeatable enough to provide a reliable product yield.

To obtain the maximum use of the substrate surface, while providing a PECVD film deposition process which can be reliably controlled, we have used a combination of at least two film deposition steps to produce a desired uniform film thickness over the entire substrate surface, where each film deposition step is one which is easily controlled. A deposition step refers to a set of process and apparatus variables which are used to deposit a film. When at least one of these variables is changed, this is considered to be a new deposition step. The deposition steps are typically carried out in a single PECVD chamber without exposing the substrate to any conditions which would cause an undesirable interface between any of the individual deposition steps which contribute to the overall thickness of a finished silicon-comprising film layer. The number of deposition steps can range from two to infinity; however, the actual number of steps used will depend on the desired total film thickness, the degree of film uniformity provided by a given number of steps, and the degree of film uniformity required for a given application. An increase in the number of deposition steps will typically increase the film uniformity over the substrate surface. However, after a certain point, the cost of adding deposition steps is not justified by the improvement in the uniformity of film thickness. When an individual deposition step can be controlled so that the average deposition rate repeatability (the average repeatability of the profile of a film deposited over a substrate) using that individual deposition step is ±3%, that deposition step is said to be easy to control. This provides a good processing window.

The change in processing variables (such as process chamber pressure or electrode spacing, by way of example and not by way of limitation) from one deposition step to another may be controlled in a digital manner where there is an abrupt change in process conditions or in an analog manner, where there is a more gradual change in process conditions. In either case, there is associated with each deposition step a time period for a given deposition step and a frequency at which various deposition steps are carried out on a time line. There is also a frequency at which individual deposition steps are carried out and a relativity between one deposition step and another. For example, deposition step one may be carried out five times, deposition step two may be carried out two times, and deposition step three may be carried out three times, where the relative order of deposition steps may be steps one, three, two, one, three, one, two, one, three, one, by way of example and not by way of limitation.

When a change in process variables (such as process chamber pressure, electrode spacing, and combinations thereof, for example) is in an analog mode, this may be accomplished in the following manner, by way of example. The electrode spacing may be adjusted over a range from about 700 mils to about 500 mils periodically by using a given nominal pulsing frequency. This 200 mil adjustment may be made at a frequency of 10 seconds. In one embodiment, for example, the spacing may move from about 700 mils to about 500 mils over a 10 second period, and then back to about 700 mils over the next 10 second period, and so on. In another embodiment, there may be a pulsing of the time period as well as the spacing. For example, the spacing may move from about 700 mils to about 500 mils over a ten second period, and then from about 500 mils to about 700 mils over a 20 second period, and so on. One skilled in the art will see that there are a number of different variations which are possible in such a scheme. With respect to process chamber pressure, the pressure may be adjusted over a range from about 2.0 Torr to about 3.0 Torr, for example, in a manner similar to that described above with respect to electrode spacing. Both the electrode spacing and process chamber pressure may be pulsed simultaneously. Changes of this kind with respect to process conditions such as electrode spacing, process pressures, and combinations thereof may be used to provide a “feathering in” or gradual transition in the thickness of a depositing layer, which transition may be beneficial in maintaining structural continuity of the film through the film thickness.

The method of the invention makes use of a combination of process steps where the individual process steps do not provide film thickness uniformity over the entire substrate surface, where the individual process steps are easy to control and provide film profile repeatability, and where the combination of steps provides film thickness uniformity over the entire substrate surface.

One skilled in the art, after having read the disclosure provided herein, can make the calculations necessary to provide a set of process steps which will enable deposition of a PECVD deposited silicon-comprising film which is uniform over an entire substrate surface with minimal experimentation.

### BRIEF DESCRIPTION OF THE DRAWINGS

FIG. 1 shows a schematic cross-sectional view of a TFT device which employs the kind of silicon-containing PECVD deposited films discussed herein.

FIG. 2A is a cross-sectional schematic of a cylindrical parallel plate, capacitively coupled reactor/deposition chamber.

FIG. 2B is a cross-sectional view of the reactor shown in FIG. 2A, taken from the center of the plasma region toward the edge (from the electrode center toward the edge of the electrode).

FIG. 3 shows a deposition rate profile for a PECVD deposited amorphous silicon film, deposited under a first set of conditions, where the deposition rate (in Å/min.) is shown as a function of the distance of travel (in mm) across a diagonal of a rectangular substrate from edge to edge in mm, where the length of the substrate was 2200 mm and the width of the substrate was 1870 mm (for a total substrate area of 4,114,000 square mm, i.e., mm²).

FIG. 4 shows a deposition rate profile for a PECVD deposited amorphous silicon film which was deposited under a second set of conditions, where the deposition rate (in Å/min.) is shown as a function of the distance of travel (in mm) across a diagonal of a rectangular substrate from edge to edge in mm, where the length of the substrate was 2200 mm and the width of the substrate was 1870 mm (for a total substrate area of 4,114,000 mm²).

FIG. 5 shows an average deposition rate profile for a PECVD deposited amorphous silicon film which was deposited under two different sets of conditions (what is referred to herein as a two step deposition). Again, the average deposition rate (in Å/min.) is shown as a function of the distance of travel (in mm) across a diagonal of a rectangular substrate from edge to edge in mm, where the length of the substrate was 2200 mm and the width of the substrate was 1870 mm (for a total substrate area of 4,114,000 mm²). In this instance the sum of the individual deposition rates across the substrate provides an average deposition rate across the substrate which enables deposition of a film having improved thickness uniformity over the thickness uniformity of the films shown in FIGS. 3 and 4.

FIG. 6 shows a PECVD processing chamber of the kind which can be used to deposit the films of the present invention.

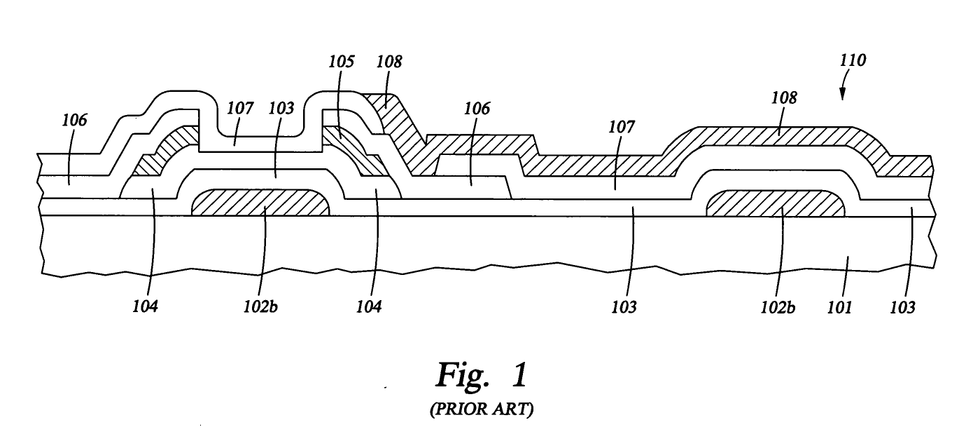

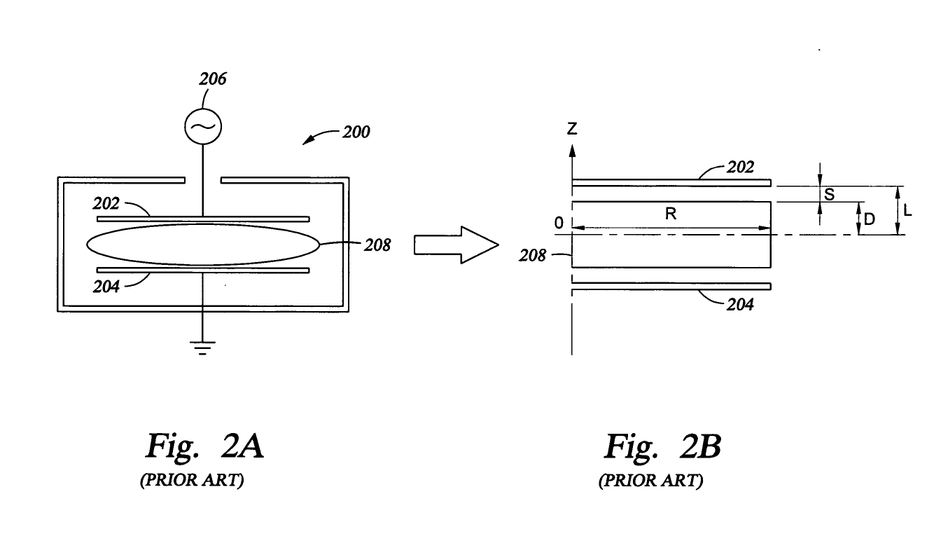

### DETAILED DESCRIPTION OF EXEMPLARY EMBODIMENTS

As a preface to the detailed description presented below, it should be noted that, as used in this specification and the appended claims, the singular forms “a”, “an”, and “the” include plural referents, unless the context clearly dictates otherwise.

When the word “about” is used herein, this means that the precision of the nominal value provided is within ±10%.

When the PECVD processing chamber used to deposit a silicon-comprising film, such as an amorphous silicon film, by way of example and not by way of limitation, is a parallel plate processing chamber, such as an AKT™ PECVD 40K System (Santa Clara, Calif.), which was used for experimental work described herein, the electrode spacing should about 1200 mils or less, and typically ranges between about 400 mils and about 1200 mils. The RF power frequency should range between about 13.56 and about 7 MHz, and may be lower; however a frequency of 2 MHz and lower is known to cause film roughness due to ion bombardment. The process chamber pressure should range between about 0.5 Torr and about 5.0 Torr (more typically, within the range of about 0.7 Torr to about 3.0 Torr). The amount of RF power/substrate surface area applied to the plasma source gas should range from about 0.01 W/cm² to about 0.5 W/cm². In addition, the total precursor gas flow rate should range from about 5,000 sccm to about 80,000 sccm.

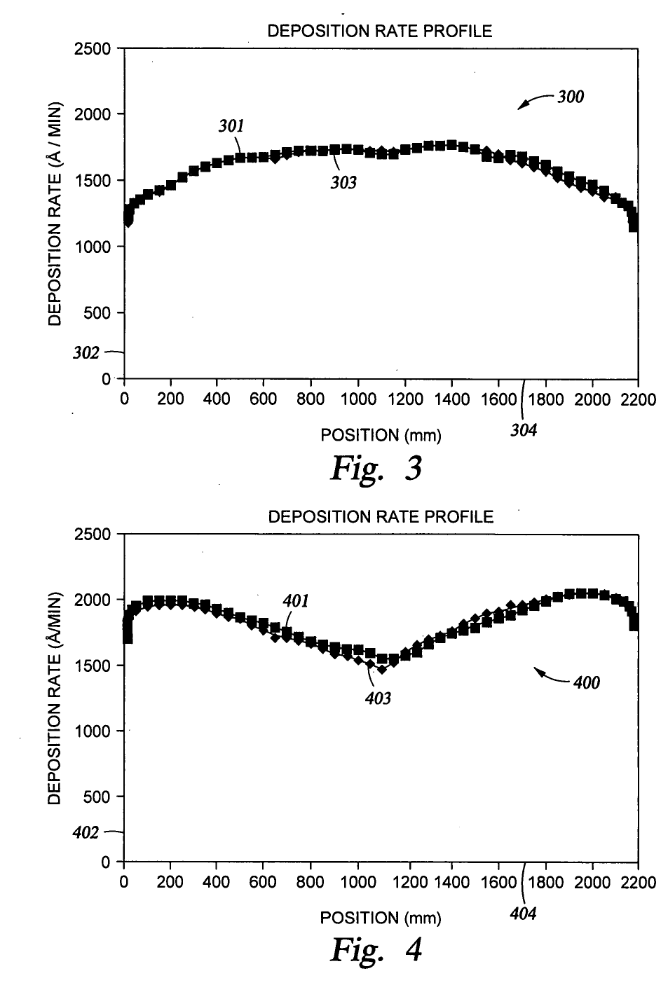

With respect to the deposition of an amorphous silicon film, the process conditions used during deposition of an amorphous silicon film deposition illustrated in FIG. 3 were: SiH₄ flow of 10,000 sccm; H₂ flow of 40,000 sccm; RF power at 11 kW; (0.27 W/cm²); RF power frequency 13.56 MHz; process chamber pressure at 2.7 Torr; electrode spacing at 550 mil (thousands of an inch); with the processing temperature ranging from about 340° C. to about 360° C. Typically the susceptor temperature is in the range of about 350° C.

The FIG. 3 graph 300 shows curves 301 and 303 illustrating the film deposition rate as measured along the two diagonals of the substrate. The deposition rate is shown in Å/min. on axis 302, with the position the position along each diagonals in mm being shown on axis 304. FIG. 3 illustrates that the thickness of the film as deposited over the substrate being thicker toward the center of the substrate and thinner toward the edges of the substrate. While the process conditions used were easy to control, ensuring accuracy and repeatability, the uniformity of the film thickness over the substrate surface is not satisfactory. The average film deposition rate over the substrate surface was 1842/min., and the variation in film thickness uniformity was 18%.

The process conditions used to deposit the film illustrated in FIG. 4 were essentially the same as those used with respect to the film illustrated in FIG. 3, except that the spacing between electrodes was changed from 550 mil to 650 mil. The FIG. 4 graph 400 shows curves 401 and 403 illustrating the film deposition rate as measured along the two diagonals of the substrate. The deposition rate is shown in Å/min. on axis 402, with the position the position along each diagonals in mm being shown on axis 404. FIG. 4 illustrates that the thickness of the film as deposited over the substrate being thinner toward the center of the substrate and thicker toward the edges of the substrate. While the process conditions used were easy to control, ensuring deposited film profile repeatability, the uniformity of the film thickness over the substrate surface is not satisfactory. The average film deposition rate over the substrate surface was 1545 Å/min., and the variation in uniformity was 17%.

Since both of the combinations of process variables described above with reference to FIGS. 3 and 4 were conditions which could be well controlled, but which did not provide the desired result, a decision was made to use a combination of process steps in deposition of a film, where a first film deposition step, step 1, was carried out using a 550 mil electrode spacing, followed by a second film deposition step, step 2 was carried out using a 650 mil electrode spacing. Both depositions were carried out in a single processing chamber, without exposing the substrate to ambient environmental conditions.

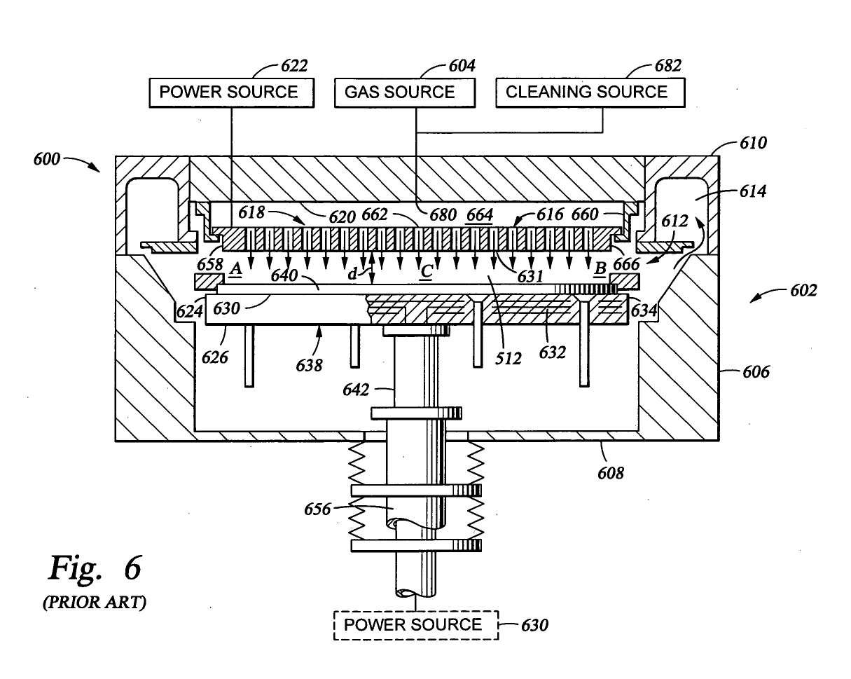

The embodiment example PECVD processes described above were carried out in a parallel plate processing chamber, the AKT™ PECVD 40 K System, which is schematically illustrated in FIG. 6. The system 600 generally includes a processing chamber 602 coupled to a gas source 604. The processing chamber 602 has walls 606 and a bottom 608 that partially define a process volume 612. The process volume 612 is typically accessed through a port (not shown) in the walls 606 that facilitate movement of a substrate 640 into and out of processing chamber 602. The walls 606 support a lid assembly 610 that contains a pumping plenum 614 that couples the process volume 612 to an exhaust port (that includes various pumping components, not shown).

A temperature controlled substrate support assembly 638 is centrally disposed within the processing chamber 602. The support assembly 638 supports the glass (for example, but not by way of limitation) substrate 640 during processing. The substrate support assembly 638 typically encapsulates at least one embedded heater 632, such as a resistive element, which element is coupled to an optional power source 630 and controllably heats the support assembly 638 and the substrate 640 positioned thereon. Typically, in a CVD process, the heater maintains the substrate 640 at a uniform temperature between about 120° C. and 460° C., depending on the processing parameters of the substrate.

Generally, the support assembly 638 has a lower side 626 and an upper side 634. The upper side 634 supports the glass substrate 640. The lower side 626 has a stem 642 coupled thereto. The stem 642 couples the support assembly 638 to a lift system (not shown) that moves the support assembly 638 between an elevated processing position (as shown) and a lowered position that facilitates substrate transfer to and from the processing chamber 602. The stem 642 additionally provides a conduit for electrical and thermocouple leads between the support assembly 638 and other components of the system 600.

The support assembly 638 is generally grounded such that RF power supplied by a power source 622 to a gas distribution plate assembly 618 positioned between the lid assembly 610 and the substrate support assembly 638 (or other electrode positioned within or near the lid assembly of the chamber) may excite gases present in the process volume 612 between the support assembly 638 and the distribution plate assembly 618. The RF power from the power source 622 is generally selected commensurate with the size of the substrate, to drive the chemical vapor deposition process. The distance “d” illustrates the spacing between the upper surface 630 of substrate support assembly 638 and the lower surface 631 of distribution plate assembly 618. The spacing “d” in combination with the thickness of the substrate 640 substantially determines the processing volume 612. The spacing “d” can be adjusted as necessary to provide the desired processing conditions.

The lid assembly 610 typically includes an entry port 680 through which process gases provided by the gas source 604 are introduced into processing chamber 602. The entry port 680 is also coupled to a cleaning source 682. The cleaning source 682 typically provides a cleaning agent, such as disassociated fluorine, that is introduced into the processing chamber 602 to remove deposition by-products and films from processing chamber hardware.

The gas distribution plate assembly 618 is coupled to an interior side 620 of the lid assembly 610. The gas distribution plate assembly 618 is typically configured to substantially follow the profile of the substrate 630, for example, polygonal for large area substrates and circular for wafers. The gas distribution plate assembly 618 includes a perforated area 616 through which process and other gases supplied from the gas source 604 are delivered to the process volume 612. The perforated area 616 of the gas distribution plate assembly 618 is configured to provide uniform distribution of gases passing through the gas distribution plate assembly 618 into the processing chamber 602.

The gas distribution plate assembly 618 typically includes a diffuser plate 658 suspended from a hanger plate 660. The diffuser plate 658 and hanger plate 660 may alternatively comprise a single unitary member. A plurality of gas passages 662 are formed through the diffuser plate 658 to allow a predetermined distribution of a precursor source gas passing through the gas distribution plate assembly 618 and into the process volume 612. The hanger plate 660 maintains the diffuser plate 658 and the interior surface 620 of the lid assembly in a spaced-apart relation, thus defining a plenum 664 therebetween. The plenum 664 allows gases flowing through the lid assembly 610 to uniformly distribute across the width of the diffuser plate 658 so that gas is provided uniformly above the center perforated area 616 and flows with a uniform distribution through gas passages 662. passing

The substrate support assembly 638, which may also referenced as a susceptor, may be raised and lowered to adjust the spacing between electrodes which was previously referred to herein. Adjustment of the electrode spacing simply requires that the substrate support assembly 638 be moved up and down within the processing chamber 602, using a Z-drive motor, for example. Film deposition may be either continued or discontinued during adjustment of the electrode spacing. An adjustment of 100 mil in the spacing requires less than 1 second.

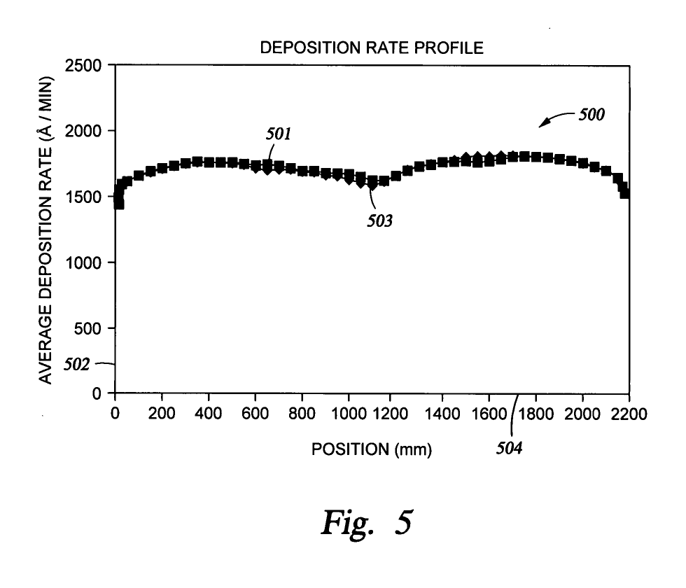

FIG. 5 graph 500 shows curves 501 and 503 illustrating the average film deposition rate for a combination of two deposition steps, where each deposition step was carried out for one half of the total deposition time period. The average film deposition rate was measured along the two diagonals of the substrate. The average film deposition rate for the combination of deposition steps is shown in Å/min. on axis 502, with the position the position along each of the substrate diagonals in mm being shown on axis 504. FIG. 5 illustrates that the thickness of the film deposited over the substrate surface is much more uniform when the two step process is used. The average film deposition rate was 1693 Å/min. and the variation in film thickness uniformity across the substrate surface was only 8%. By using a combination of two process steps which were each easy to control, a deposited film was produced where the uniformity of the film thickness over the substrate surface is acceptable.

When the PECVD processing chamber is a parallel plate processing chamber where the substrate surface area processed may be about 25,000 cm² to about 42,000 cm², such as the processing chamber used for processing the example substrates described herein with reference to FIGS. 3, 4, and 5, the electrode spacing is typically in the range from about 400 mils to about 1200 mils. The sheath width “s” is about 20 mils or greater. In addition, the total precursor gas flow rate typically ranges from 5,000 sccm to about 100,000 sccm, which typically provides a chamber precursor gas turnover ranging from about 0.015/min to about 0.07/min. The chamber precursor gas turnover refers to the rate at which the gas in the process chamber area with direct access to the substrate is replaced with new precursor gas. A turnover of 0.015/minute means 0.015 of the precursor gas in the process chamber area is removed and replaced per minute. One skilled in the art, upon reading the disclosure herein can calculate an equivalent electrode spacing and precursor gas flow rate when the plasma processing chamber is different from the processing chamber discussed herein.

During deposition of a silicon-containing film, reducing the RF power/substrate area which is applied to the plasma source so that it is within the range of about 0.01 W/cm² to about 0.6 W/cm² can aid in improving film thickness uniformity, while maintaining an acceptable film deposition rate of at least 1000 Å/min.

While the invention has been described in detail above with reference to several embodiments, various modifications within the scope and spirit of the invention will be apparent to those of working skill in this technological field. Accordingly, the scope of the invention should be measured by the appended claims.

We claim:

1. A method of increasing film deposition uniformity of a silicon-containing PECVD deposited film over a substrate surface where a minimum dimension along an edge or a minimum equivalent diameter of said substrate is about 0.5 meter, the method comprising employing a combination of at least two deposition steps, where a deposition step refers to a single set of process and apparatus variables which are used in combination to deposit a portion of said film, where each deposition step can be controlled so that reproducibility of an average film deposition rate profile over the substrate surface achieved using an individual step is within ±3%, and wherein a particular combination of deposition steps is selected so that a variation in the film thickness of a film deposited over said substrate surface using said particular combination of steps is about 10% or less.

2. A method in accordance with claim 1, wherein said silicon-containing PECVD deposited film is selected from the group consisting of polycrystalline silicon, microcrystalline silicon, amorphous silicon, and combinations thereof.

3. A method in accordance with claim 2, wherein said silicon-containing PECVD deposited film is a doped film.

4. A method in accordance with claim 1, wherein said at least two deposition steps are carried out in a single process chamber.

5. A method in accordance with claim 1 or claim 4, wherein a change from one deposition step to another deposition step is carried out in a digital manner.

6. A method in accordance with claim 1 or claim 4, wherein a change from one deposition step to another deposition step is carried out in an analog manner.

7. A method in accordance with claim 6, wherein a spacing between electrodes during said silicon-containing film PECVD deposition is adjusted over a range between about 500 mils and about 700 mils, and wherein said spacing is adjusted at a nominal frequency.

8. A method in accordance with claim 7, wherein said nominal frequency ranges between about 5 seconds and about 10 seconds.

9. A method in accordance with claim 6, wherein a spacing between electrodes during said silicon-containing film PECVD deposition is adjusted over a range between about 500 mils and about 700 mils, and wherein said spacing is adjusted at a variable frequency.

10. A method in accordance with claim 6, wherein a spacing between electrodes during said silicon-containing film PECVD deposition is adjusted over a range between about 500 mils and about 700 mils, and wherein said spacing is adjusted in a first direction at a first frequency and in a second direction at a second frequency.

11. A method in accordance with claim 1, wherein the time period of deposition for each step is the same.

12. A method in accordance with claim 1, wherein the time period of deposition of at least two individual steps is different.

13. A method in accordance with claim 1, wherein the frequency at which at least two individual steps are carried out is different.

14. A method in accordance with claim 1, wherein the order in which said individual steps are carried out varies during said film deposition.

15. A method in accordance with claim 6, wherein a time period over which a gradual change occurs is less than about 20 percent of the total time of the steps before, after, and including the gradual change time period.

16. A method of increasing film deposition uniformity of a silicon-containing PECVD deposited film over a substrate surface where a minimum dimension along an edge or a minimum equivalent diameter of said substrate is about 0.5 meter, wherein said method employs a combination of process steps where the individual process steps do not provide film thickness uniformity over said substrate surface, but are easy to control, but where the combination of individual process steps provides film thickness uniformity over said substrate surface.

17. A method in accordance with claim 16, wherein said combination of deposition steps provides a film thickness variability of 10% or less over said substrate surface.

18. A method in accordance with claim 17, wherein said at least two deposition steps are carried out in a single process chamber.

19. A method in accordance with claim 16 or claim 18, wherein a change from one deposition step to another deposition step is carried out in a digital manner.

20. A method in accordance with claim 16 or claim 18, wherein a change from one deposition step to another deposition step is carried out in an analog manner.

21. A method in accordance with claim 20, wherein a spacing between electrodes during said silicon-containing film PECVD deposition is adjusted over a range between about 500 mils and about 700 mils, and wherein said spacing is adjusted at a nominal frequency.

22. A method in accordance with claim 21, wherein said nominal frequency ranges between about 5 seconds and about 10 seconds.

23. A method in accordance with claim 20, wherein a spacing between electrodes during said silicon-containing film PECVD deposition is adjusted over a range between about 500 mils and about 700 mils, and wherein said spacing is adjusted at a variable frequency.

24. A method in accordance with claim 20, wherein a spacing between electrodes during said silicon-containing film PECVD deposition is adjusted over a range between about 500 mils and about 700 mils, and wherein said spacing is adjusted in a first direction at a first frequency and in a second direction at a second frequency.

25. A method in accordance with claim 16, wherein the time period of deposition for each step is the same.

26. A method in accordance with claim 16, wherein the time period of deposition of at least two individual steps is different.

27. A method in accordance with claim 16, wherein the frequency at which at least two individual steps are carried out is different.

28. A method in accordance with claim 16, wherein the order in which said individual steps are carried out varies during said film deposition.

29. A method in accordance with claim 20, wherein a time period over which a gradual change occurs is less than about 20 percent of the total time of the steps before, after, and including the gradual change time period.
